(19) United States
(12) Patent Application Publication
(10) Pub. No.: US 2019/0131511 A1
(43) Pub. Date: May 2, 2019

(54) SUPERCONDUCTOR-SILICON INTERFACE CONTROL

(71) Applicant: Intel Corporation, Santa Clara, CA (US)

(72) Inventors: James S. Clarke, Portland, OR (US); Jeanette M. Roberts, North Plains, OR (US); Ravi Pillarisetty, Portland, OR (US); David J. Michalak, Portland, OR (US); Zachary R. Yoscovits, Beaverton, OR (US)

(73) Assignee: Intel Corporation, Santa Clara, CA (US)

(21) Appl. No.: 16/096,235

(22) PCT Filed: Jun. 30, 2016
(86) PCT No.: PCT/US2016/040244

§ 371 Date: Oct. 24, 2018

(51) Int. Cl. H01L 39/22; H01L 39/02; H01L 39/24; H01L 27/18; H03K 19/195

(52) U.S. Cl. CPC H01L 39/223; H01L 39/025; H03K 19/195; H01L 27/18; H01L 39/2493

(57) ABSTRACT

Described herein are methods that allow reducing or eliminating formation of silicon nitride layers at superconductor-silicon interfaces, as well as quantum circuit devices fabricated using such methods. The methods include applying various surface modification techniques to silicon in order to form a controlled interfacial layer at the interface of silicon and superconductor, which interfacial layer prevents or at least minimizes formation of silicon nitride at said interface. Reducing or eliminating silicon nitride layers at superconductor-silicon interfaces in quantum circuits may help minimizing the negative effects of spurious TLS's, thereby improving on the decoherence problem of qubits.

### TECHNICAL FIELD

This disclosure relates generally to the field of quantum computing, and more specifically, to providing control of interfaces of superconductor(s) and silicon in quantum circuits.

### BACKGROUND

Quantum computing refers to the field of research related to computation systems that use quantum mechanical phenomena to manipulate data. These quantum mechanical phenomena, such as superposition (in which a quantum variable can simultaneously exist in multiple different states) and entanglement (in which multiple quantum variables have related states irrespective of the distance between them in space or time), do not have analogs in the world of classical computing, and thus cannot be implemented with classical computing devices.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIG. 1A provides a schematic illustration of a superconducting quantum circuit, according to some embodiments of the present disclosure.

FIG. 1B provides a schematic illustration of an exemplary physical layout of a superconducting quantum circuit, according to some embodiments of the present disclosure.

FIG. 1C provides a schematic illustration of an exemplary transmon, according to some embodiments of the present disclosure.

FIG. 2 provides a schematic illustration of a quantum computing device, according to some embodiments of the present disclosure.

FIG. 3 provides a schematic illustration of a quantum circuit structure comprising a silicon nitride layer at a superconductor-silicon interface.

FIG. 4 provides a schematic illustration of a quantum circuit structure comprising an interface layer configured to prevent/minimize formation of a silicon nitride layer at a superconductor-silicon interface, according to some embodiments of the present disclosure.

FIG. 5 provides a flow chart of a method for forming a quantum circuit structure comprising an interface layer configured to prevent/minimize/decrease formation of a silicon nitride layer at a superconductor-silicon interface, according to some embodiments of the present disclosure.

FIG. 6 provides a flow chart of a method for processing the surface of a silicon layer prior to deposition of an interface layer, according to some embodiments of the present disclosure

FIG. 7 provides a schematic illustration of a real-life structure comprising an interface layer configured to prevent/minimize formation of a silicon nitride layer at a superconductor-silicon interface, according to some embodiments of the present disclosure.

### DETAILED DESCRIPTION

As previously described herein, quantum computing, or quantum information processing, refers to the field of research related to computation systems that use quantum-mechanical phenomena to manipulate data. One example of quantum-mechanical phenomena is the principle of quantum superposition, which asserts that any two or more quantum states can be added together, i.e. superposed, to produce another valid quantum state, and that any quantum state can be represented as a sum of two or more other distinct states. Quantum entanglement is another example of quantum-mechanical phenomena. Entanglement refers to groups of particles being generated or interacting in such a way that the state of one particle becomes intertwined with that of the others. Furthermore, the quantum state of each particle cannot be described independently. Instead, the quantum state is given for the group of entangled particles as a whole. Yet another example of quantum-mechanical phenomena is sometimes described as a “collapse” because it asserts that when we observe (measure) particles, we unavoidably change their properties in that, once observed, the particles cease to be in a state of superposition or entanglement (i.e. by trying to ascertain anything about the particles, we collapse their state).

Put simply, superposition postulates that a given particle can be simultaneously in two states, entanglement postulates that two particles can be related in that they are able to instantly coordinate their states irrespective of the distance between them in space and time, and collapse postulates that when one observes a particle, one unavoidably changes the state of the particle and its' entanglement with other particles. These unique phenomena make manipulation of data in quantum computers significantly different from that of classical computers (i.e. computers that use phenomena of classical physics). Classical computers encode data into binary values, commonly referred to as bits. At any given time, a bit is always in only one of two states—it is either 0 or 1. Quantum computers use so-called quantum bits, referred to as qubits (both terms “bits” and “qubits” often interchangeably refer to the values that they hold as well as to the actual devices that store the values). Similar to a bit of a classical computer, at any given time, a qubit can be either 0 or 1. However, in contrast to a bit of a classical computer, a qubit can also be 0 and 1 at the same time, which is a result of superposition of quantum states. Entanglement also contributes to the unique nature of qubits in that input data to a quantum processor can be spread out among entangled qubits, allowing manipulation of that data to be spread out as well: providing input data to one qubit results in that data being shared to other qubits with which the first qubit is entangled.

Compared to well-established and thoroughly researched classical computers, quantum computing is still in its infancy, with the highest number of qubits in a solid-state quantum processor currently being about 10. One of the main challenges resides in protecting qubits from decoherence so that they can stay in their information-holding states long enough to perform the necessary calculations and read out the results. For this reason, materials, structures, and fabrication methods used for building qubits should continuously focus on reducing spurious (i.e. unintentional and undesirable) two-level systems (TLS's), thought to be the dominant source of qubit decoherence. In general, as used in quantum mechanics, a two-level (also referred to as “two-state”) system is a system that can exist in any quantum superposition of two independent and physically distinguishable quantum states. Another challenge that is unique to quantum computing is the ability to provide substantially lossless connectivity between qubits at very low powers, e.g. as low as a power of a single photon that may be present in a particular resonator interconnecting two qubits.

None of the challenges described above ever had to be addressed for classical computers, and these challenges are not easy. In particular, quantum circuits often employ superconducting materials, both in forming qubits themselves as well as in forming interconnects that aim to provide substantially lossless connectivity to, from, and between the qubits. Some examples of superconducting materials include niobium titanium nitride (NbTiN) and titanium nitride (TiN). In addition, silicon (Si) is often the material of choice when selecting substrates on which quantum circuits are to be built. However, when superconducting materials are provided on silicon, oftentimes a layer of silicon nitride (SiN) is unintentionally formed at the superconductor-silicon interface (i.e. in between the silicon and the superconducting material). Although such a silicon nitride layer is relatively thin, typically on the order of a few angstroms to a few nanometers (nm), it has been linked to exacerbating qubit decoherence problem by being a cause of spurious TLS's. Furthermore, the losses due to such a silicon nitride layer are greater for low powers, which are often used in quantum circuits. Therefore, improvements with respect to controlling the superconductor-silicon interface would be desirable.

As used herein, “superconductor-silicon interface” refers to an interface between a silicon layer that typically forms a foundation upon which a quantum circuit may be built and a bulk superconductor used in a quantum circuit for its superconductive properties. The bulk superconductor could e.g. be a bottom or a top electrode of a Josephson Junction or one of interconnects of a quantum circuit. The “superconductor-silicon interface” does not imply that such a silicon layer and the bulk superconductor are necessarily in direct contact with one another. As described above, various interfacial layers may spontaneously form between the silicon layer and the bulk superconductor, which interfacial layers may be considered to separate the silicon layer and the bulk superconductor. On the other hand, according to embodiments of the present disclosure, the silicon layer and the bulk superconductor are deliberately separated from one another by what is referred in the following as an “interface layer” configured to prevent, decrease, or minimize spontaneous and uncontrolled formation of other interfacial layers, such as e.g. silicon nitride, between the silicon layer and the bulk superconductor. In the following, unless specified otherwise, “superconductor” refers to a bulk superconductor, while “interface layer”, which may also comprise a superconductive material, refers to a relatively thin layer which typically would not exhibit the same properties as a bulk material.

As the foregoing description illustrates, building a quantum computer presents unique challenges not encountered in classical computing. The challenges are unique due to, both, the physics of data manipulation being different from that of classical computers (e.g. superposition, entanglement, and collapse), and the physical systems suitable to build quantum circuits of a quantum computer being different (e.g. the systems should be able to provide substantially lossless connectivity and be able to operate at cryogenic temperatures). Described herein are methods that allow reducing or eliminating formation of silicon nitride layers at superconductor-silicon interfaces, as well as quantum circuit devices fabricated using such methods. The methods include applying various surface modification techniques to silicon substrates in order to form a controlled interfacial layer at the interface of silicon and superconductor, which interfacial layer prevents or at least minimizes formation of silicon nitride at said interface. Reducing or eliminating silicon nitride layers at superconductor-silicon interfaces in quantum circuits may help minimizing the negative effects of spurious TLS's, thereby improving on the decoherence problem of qubits.

While some descriptions are provided with reference to superconducting qubits, teachings of the present disclosure are applicable to implementations of any qubits, including qubits other than superconducting qubits, which may require a superconducting material to be provided over silicon, all of which implementations are within the scope of the present disclosure.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Furthermore, in the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure. However, the order of description should not be construed to imply that these operations are necessarily order dependent. In particular, these operations need not be performed in the order of presentation. Operations described may be performed in a different order from the described embodiment(s). Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale.

As used herein, terms indicating what may be considered an idealized behavior, such as e.g. “superconducting” or “lossless”, are intended to cover functionality that may not be exactly ideal but is within acceptable margins for a given application. For example, a certain level of loss, either in terms of non-zero electrical resistance or non-zero amount of spurious TLS's may be acceptable such that the resulting materials and structures may still be referred to by these “idealized” terms. One metric of interest may be the decay rate associated with these losses (e.g. losses either from TLS's or residual resistance), and as long as the decay rate associated with these mechanisms is not worse than needed in order to achieve a fault-tolerant quantum calculation, then the losses are deemed acceptable and the idealized terms (e.g. superconducting or lossless) - appropriate. Specific values associated with an acceptable decay are expected to change over time as fabrication precision will improve and as fault-tolerant schemes may become more tolerant of higher decay rates. An adapted version of this metric, as well as other metrics suitable for a particular application in determining whether certain behavior may be referred to using idealized terms, are within the scope of the present disclosure.

For purposes of illustrating the techniques for reducing or eliminating formation of silicon nitride layers at superconductor-silicon interfaces of quantum circuits, described herein, it is important to understand the activities that may be present in a typical quantum circuit. The following foundational information may be viewed as a basis from which the present disclosure may be properly explained. Such information is offered for purposes of explanation only and, accordingly, should not be construed in any way to limit the broad scope of the present disclosure and its potential applications.

As previously briefly explained above, quantum computing refers to the use of quantum mechanical properties to perform calculations. Some of these properties include superposition and entanglement. Just as classical computers are composed of bits that can either be in a 1 or a 0 state, a quantum computer is composed of quantum bits (i.e., qubits) which have states of |0 [symbol] and |1 [symbol] . Quantum mechanics allows for superpositions of the |0 [symbol] and |1 [symbol] states with a general form of a|0 [symbol] +b|1 [symbol] where a and b are complex numbers. When a qubit state is measured, it collapses to either state |0 [symbol] with a probability of that happening being |a|², or to state |1 [symbol] with a probability of the latter being |b|². Taking into account the fact that |a|²+|b|²=1 (since the total probability must sum to unity) and ignoring an overall phase factor which does not have any observable effects, the general state can be re-written as

$$cos \frac{θ}{2} \vert 0 〉 + {e}^{i ϕ} sin \frac{θ}{2} \vert 1 〉 ,$$

where φ is the phase difference between the two states.

Entanglement occurs when the interaction between two particles (e.g. two qubits) is such that the states of the two cannot be specified independently, but rather can only be specified for the whole system. This causes the states of the two qubits to be linked together such that measurement of one of the qubits, causes the state of the other qubit to collapse.

In order to realize a quantum computer, a physical system that can act as a qubit is needed. Such a system needs to have at least two states to act as 0 and 1 states. Note that it is not necessary to have a system with exactly only two states if the spacing between each energy level is different, such that each level can be addressed individually.

As illustrated above, ability to manipulate and read out quantum states, making quantum-mechanical phenomena visible and traceable, and ability to deal with and improve on the fragility of quantum states of a qubit present unique challenges not found in classical computers. These challenges explain why so many current efforts of the industry and the academics continue to focus on a search for new and improved physical systems whose functionality could approach that expected of theoretically designed qubits. Physical systems for implementing qubits that have been explored until now include e.g. superconducting qubits, single trapped ion qubits, silicon (Si) quantum dot qubits, photon polarization qubits, etc.

Out of the various physical implementations of qubits listed above, superconducting qubits are promising candidates for building a quantum computer.

Three classes are typically differentiated within a family of superconducting qubits: charge qubits, flux qubits (also known as “persistent current qubits”) and phase qubits, depending on whether a variable that defines the quantum states is, respectively, charge, flux, or phase. In addition to these three classes, there also exist hybrid qubits that are mixtures of two or more of these classes.

Superconducting qubits operate based on the Josephson effect, which refers to a macroscopic quantum phenomenon of supercurrent, i.e. a current that, due to zero electrical resistance, flows indefinitely long without any voltage applied, across a device known as a Josephson Junction. Josephson Junctions are integral building blocks in superconducting quantum circuits where they form a basis of quantum circuit elements that can approximate functionality of theoretically designed qubits.

In some implementations, namely when superconducting qubits are implemented as transmon qubits, two basic elements of superconducting quantum circuits are inductors and capacitors. However, circuits made using only these two elements cannot make a system with two energy levels because, due to the even spacing between the system's energy levels, such circuits will produce harmonic oscillators with a ladder of equivalent states. A nonlinear element is needed to have an effective two-level quantum state system, or qubit. Josephson Junction is an example of such non-linear, non-dissipative circuit element.

Josephson Junctions may form the central circuit elements of a superconducting quantum computer. A Josephson Junction may include a thin layer of insulator, typically referred to as a barrier or a tunnel barrier, sandwiched between two layers of superconductor. The Josephson Junction acts as a superconducting tunnel junction. Cooper pairs tunnel across the barrier from one superconducting layer to the other. The electrical characteristics of this tunneling are governed by so-called Josephson relations which provide the basic equations governing the dynamics of the Josephson effect:

$$\begin{matrix}I = {I}_{c} sin ϕ & ( 1 ) \\ V = \frac{ℏ}{2 e} \dot{ϕ} & ( 2 )\end{matrix}$$

In these equations, φ is the phase difference in the superconducting wave function across the junction, I_{c} (the critical current) is the maximum current that can tunnel through the junction, which depends on the barrier thickness and the area of the junction, V is the voltage across the Josephson Junction, I is the current flowing through the Josephson Junction, ℏ is the reduced Planck's constant, and e is electron's charge. Equations (1) and (2) can be combined to give an equation (3):

$$V = \frac{ℏ}{2 e {I}_{c} cos ϕ} \dot{I} \qquad ( 3 )$$

Equation (3) looks like the equation for an inductor with inductance L:

$$L = \frac{ℏ}{2 {eI}_{c} cos ϕ} \qquad ( 4 )$$

Since inductance is a function of φ, which itself is a function of I, the inductance of a Josephson Junction is non-linear, which makes an LC circuit formed using a Josephson Junction as the inductor have uneven spacing between its energy states.

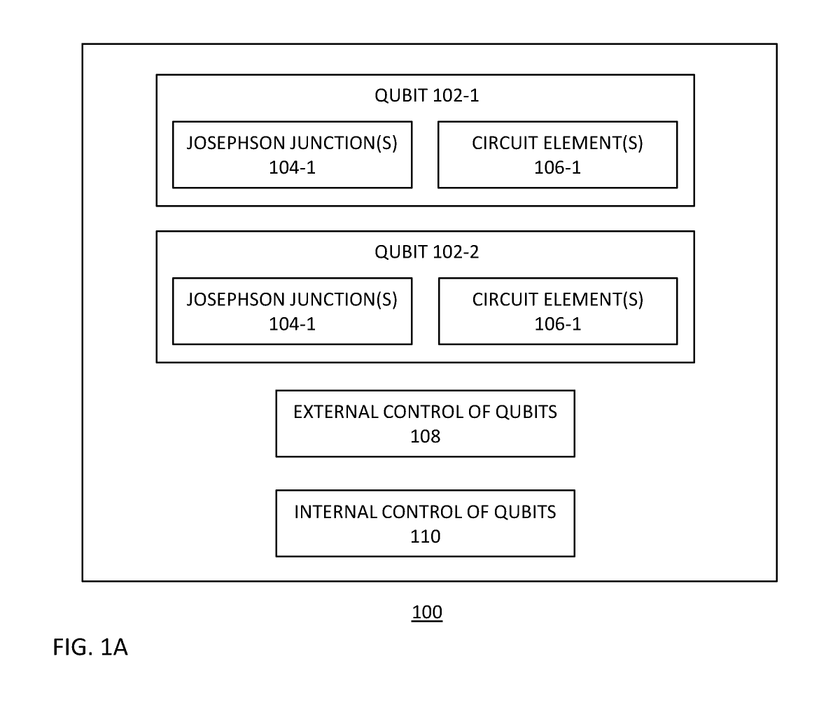

The foregoing provides an illustration of using a Josephson Junction in a transmon, which is one type of superconducting qubit. In other classes of superconducting qubits, Josephson Junctions combined with other circuit elements have similar functionality of providing the non-linearity necessary for forming an effective two-level quantum state, or qubit. In other words, when implemented in combination with other circuit elements (e.g. capacitors in transmons or superconducting loops in flux qubits), one or more Josephson Junctions allow realizing a quantum circuit element which has uneven spacing between its energy levels resulting in a unique ground and excited state system for the qubit. This is illustrated in FIG. 1A, providing a schematic illustration of a superconducting quantum circuit 100, according to some embodiments of the present disclosure. As shown in FIG. 1A, an exemplary superconducting quantum circuit 100 includes two or more qubits 102 (reference numerals following after a dash, such as e.g. qubit 102-1 and 102-2 indicate different instances of the same or analogous element). Each of the superconducting qubits 102 may include one or more Josephson Junctions 104 connected to one or more other circuit elements 106, which, in combination with the Josephson Junction(s) 104, form a non-linear circuit providing a unique two-level quantum state for the qubit. The circuit elements 106 could be e.g. capacitors in transmons or superconducting loops in flux qubits.

As also shown in FIG. 1A, an exemplary superconducting quantum circuit 100 typically includes means 108 for providing external control of qubits 102 and means 110 for providing internal control of qubits 102. In this context, “external control” refers to controlling the qubits 102 from outside of, e.g, an integrated circuit (IC) chip comprising the qubits, including control by a user of a quantum computer, while “internal control” refers to controlling the qubits 102 within the IC chip. For example, if qubits 102 are transmon qubits, external control may be implemented by means of flux bias lines (also known as “flux lines” and “flux coil lines”) and by means of readout and drive lines (also known as “microwave lines” since qubits are typically designed to operate with microwave signals), described in greater detail below. On the other hand, internal control lines for such qubits may be implemented by means of resonators, e.g., coupling and readout resonators, also described in greater detail below.

Any one of the qubits 102, the external control means 108, and the external control means 110 of the quantum circuit 100 may be provided on, over, or at least partially embedded in a substrate or an interconnect support layer (ISL) (not shown in FIG. 1A), which two terms may be used interchangeably. A substrate/ISL may include any substrate/ISL suitable for realizing quantum circuit components, as described above. In one implementation, the substrate/ISL may be a crystalline substrate/ISL such as, but not limited to a silicon or a sapphire substrate/ISL, and may be provided as a wafer or a portion thereof. In other implementations, the substrate/ISL may be non-crystalline. In general, any material that provides sufficient advantages (e.g. sufficiently good electrical isolation and/or ability to apply known fabrication and processing techniques) to outweigh the possible disadvantages (e.g. negative effects of spurious TLS's), and that may serve as a foundation upon which a quantum circuit may be built, falls within the spirit and scope of the present disclosure. Additional examples of substrates include silicon-on-insulator (SOI) substrates, III-V substrates, and quartz substrates.

As previously described herein, within superconducting qubit implementations, three classes are typically distinguished: charge qubits, flux qubits, and phase qubits. Transmons, a type of charge qubits with the name being an abbreviation of “transmission line shunted plasma oscillation qubits”, are particularly encouraging because they exhibit reduced sensitivity to charge noise. FIG. 1B provides a schematic illustration of an exemplary physical layout of a superconducting quantum circuit 100B where qubits are implemented as transmons, according to some embodiments of the present disclosure.

Similar to FIG. 1A, FIG. 1B illustrates two qubits 102. In addition, FIG. 1B illustrates flux bias lines 112, microwave lines 114, a coupling resonator 116, a readout resonator 118, and wirebonding pads 120 and 122. The flux bias lines 112 and the microwave lines may be viewed as examples of the external control means 108 shown in FIG. 1A. The coupling resonator 116 and the readout resonator 118 may be viewed as examples of the internal control means 110 shown in FIG. 1A.

Running a current through the flux bias lines 112, provided from the wirebonding pads 120, allows tuning (i.e. changing) the frequency of the corresponding qubits 102 to which each line 112 is connected. In general, flux control may operate in the following manner. As a result of running the current in a particular flux bias line 112, magnetic field is created around the line. If such a magnetic field is in sufficient proximity to the qubit 102, e.g. by a portion of the flux bias line 112 being provided next to the qubit 102, the magnetic field couples to the qubit, thereby changing the spacing between the energy levels of the qubit. This, in turn, changes the frequency of the qubit since the frequency is directly related to the spacing between the energy levels via Planck's equation. The Planck's equation is E=hv, where E is the energy (in this case the energy difference between energy levels of a qubit), h is the Planck's constant and v is the frequency (in this case the frequency of the qubit). As this equation illustrates, if E changes, then v changes. Provided there is sufficient multiplexing, different currents can be sent down each of the flux lines allowing for independent tuning of frequencies of the various qubits.

Typically, the qubit frequency may be controlled in order to bring the frequency either closer to or further away from another resonant item, for example a coupling resonator such as 116 shown in FIG. 1B that connects two or more qubits together, as may be desired in a particular setting. For example, if it is desirable that a first qubit 102 (e.g. the qubit 102 shown on the left side of FIG. 1B) and a second qubit 102 (e.g. the qubit 102 shown on the right side of FIG. 1B) interact, via the coupling resonator 116 connecting these qubits, then both qubits 102 may need to be tuned to be at nearly the same frequency. On the other hand, it may sometimes be desirable that two qubits coupled by a coupling resonator do not interact, i.e. the qubits are independent. In this case, by applying magnetic flux to one qubit it is possible to cause the frequency of the qubit to change enough so that the photon it could emit no longer has the right frequency to resonate on the coupling resonator. If there is nowhere for such a frequency-detuned photon to go, the qubit will be better isolated from its surroundings and will live longer in its current state. Thus, in general, two or more qubits could be configured to avoid or eliminate interactions with one another by tuning their frequencies to specific values or ranges.

The state(s) of each qubit 102 may be read by way of its corresponding readout resonator 118. As explained below, the qubit 102 induces a shift in the resonant frequency in the readout resonator 118. This resonant frequency is then passed to the microwave lines 114 and communicated to the pads 122.

To that end, a readout resonator 118 may be provided for each qubit. The readout resonator 118 may be a transmission line that includes a capacitive connection to ground on one side and is either shorted to the ground on the other side (for a quarter wavelength resonator) or has a capacitive connection to ground (for a half wavelength resonator), which results in oscillations within the transmission line (resonance), with the resonant frequency of the oscillations being close to the frequency of the qubit. The readout resonator 118 is coupled to the qubit by being in sufficient proximity to the qubit 102, more specifically in sufficient proximity to the capacitor of the qubit 102, when the qubit is implemented as a transmon, either through capacitive or inductive coupling. Due to a coupling between the readout resonator 118 and the qubit 102, changes in the state of the qubit 102 result in changes of the resonant frequency of the readout resonator 118. In turn, because the readout resonator 118 is in sufficient proximity to the microwave line 114, changes in the resonant frequency of the readout resonator 118 induce changes in the current in the microwave line 114, and that current can be read externally via the wirebonding pads 122.

The coupling resonator 116, also known as a bus resonator, allows coupling different qubits together in order to realize quantum logic gates. The coupling resonator 116 is similar to the readout resonator 118 in that it is a transmission line that includes capacitive connections to ground on both sides (i.e. a half wavelength resonator), which also results in oscillations within the coupling resonator 116. Each side of the coupling resonator 116 is coupled (again, either capacitively or inductively) to a respective qubit by being in sufficient proximity to the qubit, namely in sufficient proximity to the capacitor of the qubit, when the qubit is implemented as a transmon. Because each side of the coupling resonator 116 has coupling with a respective different qubit, the two qubits are coupled together through the coupling resonator 116. In this manner, state of one qubit depends on the state of the other qubit, and the other way around. Thus, coupling resonators may be employed in order to use a state of one qubit to control a state of another qubit.

In some implementations, the microwave line 114 may be used to not only readout the state of the qubits as described above, but also to control the state of the qubits. When a single microwave line is used for this purpose, the line operates in a half-duplex mode where, at some times, it is configured to readout the state of the qubits, and, at other times, it is configured to control the state of the qubits. In other implementations, microwave lines such as the line 114 shown in FIG. 1B may be used to only readout the state of the qubits as described above, while separate drive lines such as e.g. drive lines 124 shown in FIG. 1B, may be used to control the state of the qubits. In such implementations, the microwave lines used for readout may be referred to as readout lines (e.g. readout line 114), while microwave lines used for controlling the state of the qubits may be referred to as drive lines (e.g. drive lines 124). The drive lines 124 may control the state of their respective qubits 102 by providing, using e.g. wirebonding pads 126 as shown in FIG. 1B, a microwave pulse at the qubit frequency, in the form of an electric field, which in turn stimulates (i.e. triggers) a transition between the 0 and 1 state of the qubit. By varying the length of this pulse, a partial transition can be stimulated, giving a superposition of the 0 and 1 states of the qubit.

As the foregoing description illustrates, while both flux bias lines 112 and drive lines 124 may be used for controlling a qubit, their forms of qubit control are fundamentally different in that a flux bias line applies magnetic field to a SQUID region of a qubit to control the frequency of the qubit, while a drive line applies a pulse to the qubit in the form of an electric field that causes a rotation of the qubit about the Bloch sphere to represent a desired superposition of a qubit.

Flux bias lines, microwave lines, coupling resonators, drive lines, and readout resonators, such as e.g. those described above, together may form interconnects for supporting propagation of microwave signals. Further, any other connections for providing direct electrical interconnection between different quantum circuit elements and components, such as e.g. connections from electrodes of Josephson Junctions to plates of the capacitors or to superconducting loops of superconducting quantum interference devices (SQUIDS) or connections between two ground lines of a particular transmission line for equalizing electrostatic potential on the two ground lines, are also referred to herein as interconnects. Still further, the term “interconnect” may also be used to refer to elements providing electrical interconnections between quantum circuit elements and components and non-quantum circuit elements, which may also be provided in a quantum circuit, as well as to electrical interconnections between various non-quantum circuit elements provided in a quantum circuit. Examples of non-quantum circuit elements which may be provided in a quantum circuit may include various analog and/or digital systems, e.g. analog to digital converters, mixers, multiplexers, amplifiers, etc.

In various embodiments, the interconnects as shown in FIG. 1B could have different shapes and layouts. For example, some interconnects may comprise more curves and turns while other interconnects may comprise less curves and turns, and some interconnects may comprise substantially straight lines. In some embodiments, various interconnects may intersect one another, in such a manner that they don't make an electrical connection, which can be done by using e.g. a bridge, bridging one interconnect over the other. As long as these interconnects operate in accordance with use of these interconnects as known in the art for which some exemplary principles were described above, quantum circuits with different shapes and layouts of the interconnects than those illustrated in FIG. 1B are all within the scope of the present disclosure.

Coupling resonators and readout resonators may be configured for capacitive coupling to other circuit elements at one or both ends in order to have resonant oscillations, whereas flux bias lines and microwave lines may be similar to conventional microwave transmission lines because there is no resonance in these lines. Each one of these interconnects may be implemented as a coplanar waveguide, which is one type of transmission line. A stripline is another type of a transmission line. Typical materials to make the interconnects include aluminum (Al), niobium (Nb), niobium nitride (NbN), titanium nitride (TiN), and niobium titanium nitride (NbTiN), all of which are particular types of superconductors. However, in various embodiments, other suitable superconductors may be used as well.

As previously described herein, FIG. 1B illustrates an embodiment specific to transmons. Subject matter of the present disclosure is not limited in this regard and may include other embodiments of quantum circuits implementing other physical systems to act as qubits, e.g. quantum dot qubits, that would also superconductor-silicon interfaces as described herein, all of which are within the scope of the present disclosure.

FIG. 1C illustrates an exemplary transmon 128 which could be used as any one of the qubits 102, according to some embodiments of the present disclosure. Presence of a capacitor 130 of such a size that capacitive energy is significantly larger than the Josephson energy in a qubit of FIG. 1C indicates that the qubit is a transmon. The capacitor 130 is configured to store energy in an electrical field as charges between the plates of the capacitor.

The capacitor 130 is depicted as an interdigitated capacitor, a particular shape of capacitor that provides a large capacitance with a small area, however, in various embodiments, other shapes and types of capacitors may be used as well. For example, such a capacitor could be implemented simply as two parallel plates with vacuum in between. Furthermore, in various embodiments, the capacitor 130 may be arranged in any direction with respect to the SQUID or a single Josephson Junction, not necessarily as shown in FIG. 1C.

In addition, the transmon illustrated in FIG. 1C includes two Josephson Junctions 132 incorporated into a superconducting loop 134. The two Josephson Junctions 132 and the superconducting loop 134 together form a superconducting quantum interference device (SQUID). Magnetic fields generated by the flux bias line 112 connected to the qubit extend to the SQUID (i.e. current in the flux bias line 112 create magnetic fields around the SQUID), which in turn tunes the frequency of the qubit.

In other embodiments, a SQUID could include only one Josephson Junction, or a transmon could be implemented with a single Josephson Junction without the superconducting loop. A single Josephson Junction without the SQUID is insensitive to magnetic fields, and thus, in such an implementation, flux bias lines 112 may not be used to control the frequency of the transmon.

While FIGS. 1A and 1B illustrate examples of quantum circuits comprising only two qubits 102, embodiments with any larger number of qubits are possible and are within the scope of the present disclosure. Superconductor-silicon interface control in quantum circuit elements as those shown in FIGS. 1A-1C, implemented e.g. when fabricating the coupling resonator 114, may be carried out by means of silicon surface modification methods as described herein.

Furthermore, while the present disclosure includes references to microwave signals, this is done only because current qubits are designed to work with such signals because the energy in the microwave range is higher than thermal excitations at the temperature that qubits are operated at. In addition, techniques for the control and measurement of microwaves are well known. For these reasons, typical frequencies of superconducting qubits are in 5-10 gigahertz (GHz) range, in order to be higher than thermal excitations, but low enough for ease of microwave engineering. However, advantageously, because excitation energy of qubits is controlled by various circuit elements, qubits can be designed to have any frequency. Therefore, in general, qubits could be designed to operate with signals in other ranges of electromagnetic spectrum and embodiments of the present disclosure could be modified accordingly. All of these alternative implementations are within the scope of the present disclosure.

In various embodiments, quantum circuits such as the one shown in FIGS. 1A-1B as well as quantum circuits implementing different physical systems to function as qubits, e.g. quantum dot qubits, may be used to implement components associated with a quantum integrated circuit (IC). Such components may include those that are mounted on or embedded in a quantum IC, or those connected to a quantum IC. The quantum IC may be either analog or digital and may be used in a number of applications within or associated with quantum systems, such as e.g. quantum processors, quantum amplifiers, quantum sensors, etc., depending on the components associated with the integrated circuit. The integrated circuit may be employed as part of a chipset for executing one or more related functions in a quantum system.

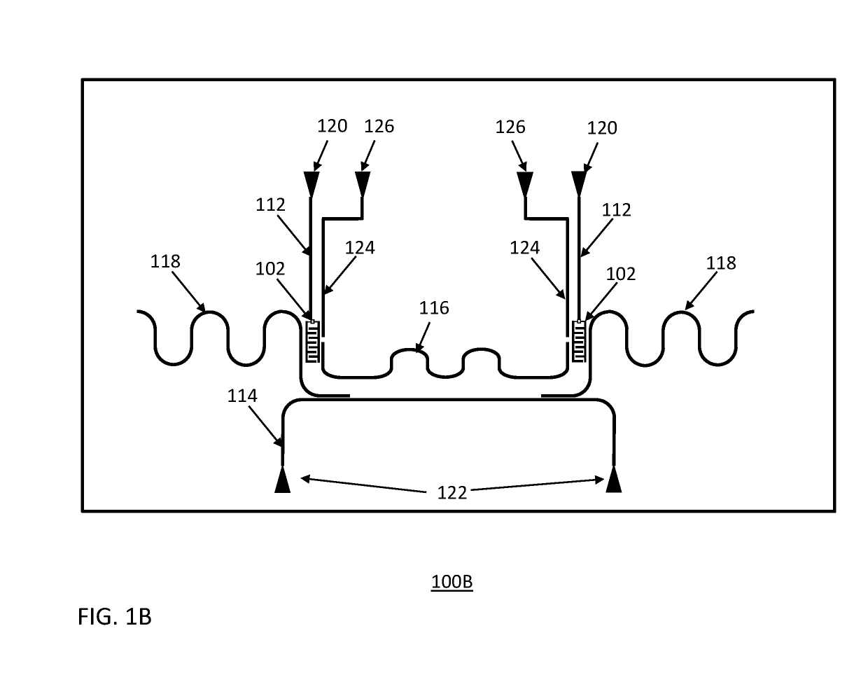

FIG. 2 provides an illustration of quantum computing device, e.g. a quantum computer, 200, according to some embodiments of the present disclosure. The computing device 200 may be any electronic device that processes quantum information. In some embodiments, the computing device 200 may include a number of components, including, but not limited to, a quantum processor 202, a memory 204, and a cryogenic apparatus 206, as shown in FIG. 2. Each of the quantum processor 202 and the memory 204 may include one or more quantum circuits comprising structures implementing qubits, e.g. qubits as described with reference to FIGS. 1A-1C or qubits implemented as different physical systems, such as e.g. quantum dot qubits, where control of superconductor-silicon interfaces may be carried out by means of surface modification techniques as described herein.

The processor 202 may be a universal quantum processor or a specialized quantum processor configured to run quantum simulations, or one or more of particular quantum algorithms. The term “processor” may refer to any device or portion of a device that processes electronic data from registers and/or memory to transform that electronic data into other electronic data that may be stored in registers and/or memory. In some embodiments, the processor 202 may be configured to execute algorithms that may be particularly suitable for quantum computers, such as e.g. cryptographic algorithms that utilize prime factorization, algorithms to optimize chemical reactions, or protein folding algorithms. The term “processor” may refer to any device or portion of a device that processes quantum information.

In various embodiments, the computing device 200 may include other components not shown in FIG. 2, such as e.g. one or more of a controller, I/O channels/devices, supplementary microwave control electronics, multiplexer, signal mixers, a user interface, as well as other quantum devices such as e.g. quantum amplifiers, quantum sensors, which quantum devices may also implement certain embodiments of the present disclosure related to control superconductor-silicon interfaces by means of silicon surface modification techniques.

In various embodiments, the computing device 200 may be included within a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 200 may be any other quantum electronic device that processes data by utilizing quantum mechanical phenomena.

In order to highlight the advantages offered by the structures and methods proposed herein, it would be helpful to first describe the nature of superconductor-silicon interfaces in conventional quantum circuits.

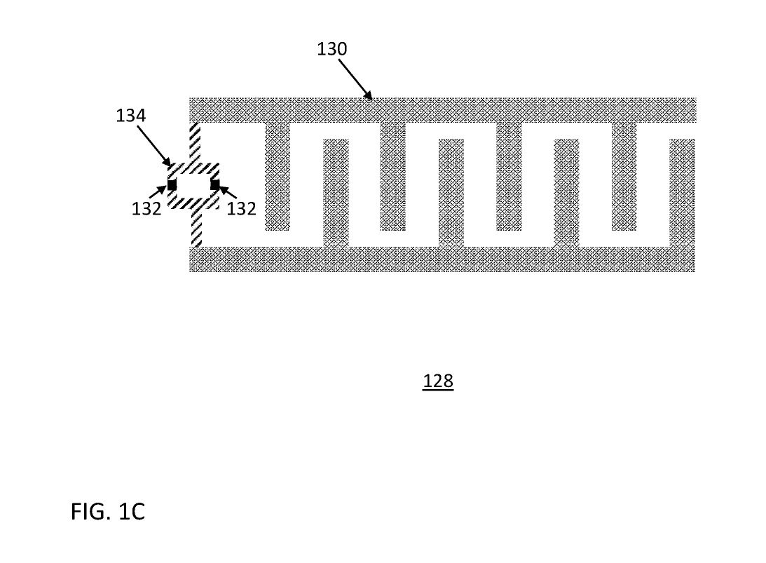

FIG. 3 provides a schematic illustration of a quantum circuit structure 300 that includes a silicon layer 302 on which a superconductor 304 is provided. The silicon layer 302 could be a part of a substrate, e.g. a silicon substrate or a SOI substrate, or could be a silicon layer provided over any other substrate for forming quantum circuits thereon. The superconductor 304 could be any element of a superconducting quantum circuit that needs to be superconducting at typical qubit operating temperatures, such as e.g. a resonator of a superconducting qubit circuit (e.g. a coupling resonator), a drive line of a superconducting qubit circuit, the bottom electrode of a Josephson junction, the top electrode of a Josephson junction, or an interconnect of a quantum circuit comprising qubits other than superconducting qubits, such as e.g. quantum dot qubits.

Sometimes the superconductor 304 may be a metal nitride, such as e.g. NbTiN or TiN, because such compounds advantageously exhibit superconductivity at typical qubit operating temperatures. In such a case, a silicon nitride layer may spontaneously form at an interface between the silicon layer 302 and the superconductor 304. This is illustrated in FIG. 3 with a silicon nitride layer 306 between the silicon layer 302 and the superconductor 304. Presence of the silicon nitride layer 306 has been linked to losses due to the spurious TLS's, which may lead to decoherence of already fragile qubits. Such losses may be especially significant in context of quantum circuits where, sometimes, energy as small as that of a single photon is to be transmitted or sustained, making any loss tolerance very low.

Embodiments of the present disclosure are based on an insight that surface modification techniques may be used to provide an interface layer between a silicon layer and a superconductor layer that would suppress (i.e. reduce) or altogether eliminate/block formation of a silicon nitride layer such as the layer 306.

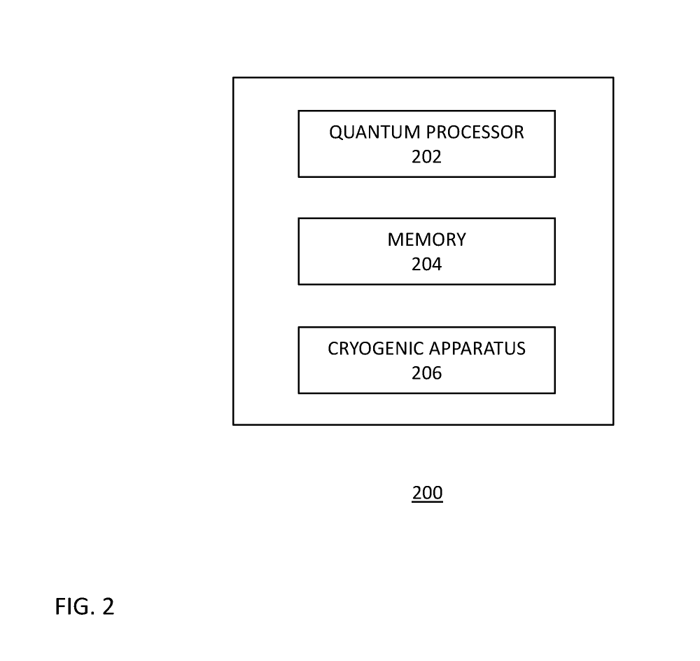

FIG. 4 provides a schematic illustration of a quantum circuit structure 400 comprising an interface layer 408 configured to prevent, minimize, or decrease formation of a silicon nitride layer at a superconductor-silicon interface, according to some embodiments of the present disclosure. As shown in FIG. 4, the interface layer 408 is provided between a superconductor 404 and a silicon layer 402.

Similar to the silicon layer 302 shown in FIG. 3, the silicon layer 402 may be a part of a substrate, e.g. a silicon substrate or a SOI substrate, or may be a silicon layer provided over any other substrate for forming quantum circuits thereon.

Similar to the superconductor 304, the superconductor 404 could be any element of a superconducting quantum circuit that needs to be superconducting at typical qubit operating temperatures, such as e.g. a resonator of a superconducting qubit circuit (e.g. a coupling resonator), a drive line of a superconducting qubit circuit, a bottom electrode of a Josephson Junction, or an interconnect of a quantum circuit comprising qubits other than superconducting qubits, such as e.g. quantum dot qubits.

In some embodiments, the interface layer 408 may not be continuous, i.e. at some points the silicon layer 402 and the superconductor 404 may come into direct contact. However, in other embodiments, the interface layer 408 may continuously cover all portions of the silicon layer 402 over which the superconductor 404 is to be disposed, thus preventing/blocking or at least reducing formation of silicon nitride at all superconductor-silicon interfaces. Various interface layers that could be used as the interface layer 408 as described herein may be one or more of plasma-stable, thermally stable, or electrochemically stable and may provide low-loss interfacial layers onto which a superconductor could be deposited using any of the known techniques.

In general, the term “plasma-stable” refers to layers that are thermodynamically stable against plasma treatment typically present during superconductor deposition or deposition of other materials. On the other hand, the term “thermally stable” refers to layers that are thermodynamically stable against downstream thermal processing steps, such as those thermal processes that would be present during e.g. the ALD/CVD, e-beam deposition, or electrodeposition processes that may be used to deposit a subsequent layer (i.e. interfacial or bulk superconducting layer). The term “electrochemically stable” may refer to layers that are thermodynamically stable against either direct electroplating or other electroless deposition schemes that could be used to deposit any subsequent material.

One class of materials which could be used as the interface layer 408 include organic-based materials, such as e.g. compounds containing alkynyl, methyl, ethyl, or other alkyl groups. Thickness of the interface layer 408 made of such materials could be selected based on various considerations. For example, on one hand, thickness of the interface layer 408 may be selected to be small enough to minimize losses, since such materials would typically be non-crystalline and, therefore, may result in higher losses due to spurious TLS's. At the same time, such a thickness is preferably sufficient to separate the superconductor 404 from the silicon layer 402 as to prevent or minimize formation of silicon nitride. For example, a thickness between 0.1 and 10 nm, including all values and ranges therein, e.g. between 0.1 and 5 nm, could be appropriate for an organic-based interface layer 408.

Another class of materials which could be used as the interface layer 408 include metal-based materials, such as e.g. compounds containing one or more of aluminum (Al), indium (In), titanium (Ti), titanium nitride (TiN), niobium (Nb), and an alloy of niobium and titanium (NbTi). Again, thickness of the interface layer 408 made of such materials could be selected based on various considerations. For example, on one hand, thickness of a metal-based interface layer 408 may be selected to be small enough to ensure that the majority of superconductivity expected from the quantum circuit element that is implemented by the superconductor 404 (e.g. a coupling resonator) comes from the superconductor 404 itself and not from the interface layer 408. At the same time, similar to the consideration of minimum thickness provided above for the organic-based layer, such a thickness is preferably sufficient to prevent formation of silicon nitride below or above the interface layer 408. For example, a thickness between 1 and 30 nm could be appropriate for a metal-based interface layer 408.

In some other embodiments, the interface layer 408 may include a combination of two or more layers of the two classes of materials described above. For example, the interface layer 408 may include one or more layers of one or more of the organic-based materials provided over the silicon surface 402 and one or more layers of one or more metal-based layers provided over the one or more of the organic-based layers. Thickness of such materials could be selected e.g. based on a combination of considerations described above. For example, a thickness between 0.1 and 5-10 nm may be appropriate for the one or more of the organic-based layers, and a thickness between 1 and 30 nm could be appropriate for the one or more of the metal-based layers disposed on the one or more organic-based layers.

In general, chemical composition of the interface layer 408 would typically be different from that of the upper superconductor 404. Thus, even when the interface layer 408 is a metal-based layer, it would typically be made of a material different in either atomic element or alloy composition from that of the superconductor 404. For example, the interface layer 408 could be Ti, while the superconductor 404 could be TiN, or the interface layer 408 could be TiN, while the superconductor 404 would be NbTiN, etc.

Because the interface layer 408 is provided to prevent or decrease formation of nitrogen-containing compounds between the surface of the silicon layer and the bulk superconductor, amount of nitrogen or any nitrogen-containing compounds within the interface layer 408 itself should be below a certain threshold. Ideally, the interface layer does not contain any nitrogen that could bond with silicon atoms of the silicon surface on which the interface layer is disposed, thus preventing formation of any silicon nitride on the silicon layer. However, just how effective the interface layer should be in preventing formation of silicon nitride and, hence, a limit/threshold of how much nitrogen can such a layer contain, would depend on factors such as e.g. what is considered to be an adequate quantum computing performance in a given setting. Certain architectures can allow for more or less well performing qubits, resonators, and other quantum circuit components where superconductor-silicon interfaces may be present, and, therefore, would affect what is considered an acceptable threshold of how much nitrogen can be present in the interface layers described herein. For example, some interface layers configured to prevent or decrease formation of nitrogen-containing compounds between the surface of the silicon layer and the bulk superconductor could comprise one or more of a carbon-containing organic layer, a thin metallic or superconducting metal layer different from the bulk superconductor, and/or a superconducting layer with graded nitrogen content from nearly zero at the Si interface to a stabilized bulk composition.

The amount of nitrogen in the interface layer provided between the silicon layer and the bulk superconductor could be determined using e.g. compositional line analysis or transmission electron microscopy (TEM) or various forms of secondary ion mass spectroscopy (SIMS); either time-of-flight (TOF-SIMS) or dynamic (DSIMS).

Examples of superconductors 404 that may benefit from being separated from the silicon layer 402 by using an interface layer described herein, such as e.g. the layer 408, include, but are not limited to metal nitrides (e.g. niobum nitride (NbN), niobium titanium nitride (NbTiN), titanium nitride (TiN)) as well as to other elements and compounds such as e.g. aluminum (Al), niobium (Nb), molybdenum rhenium (MoRe), etc., or any alloy of two or more superconducting materials. In general, any material that exhibits superconductivity at typical qubit operating temperatures could be used as the superconductor 404 and be separated from the silicon layer 402 by the interface layer 408.

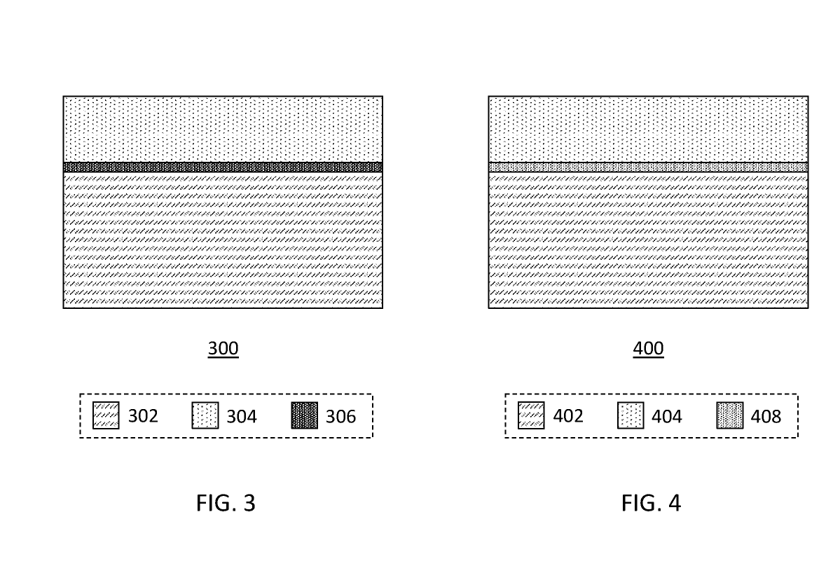

FIG. 5 provides a flow chart of a method 500 for forming a quantum circuit structure comprising an interface layer, such as e.g. the interface layer 408, configured to prevent, minimize, or decrease the likelihood of formation of a silicon nitride layer at a superconductor-silicon interface, according to some embodiments of the present disclosure. In the following description of FIG. 5, references are made to the structure shown in FIG. 4. However, discussions provided for the method of FIG. 5 are applicable to any other structures and corresponding methods of their fabrication, e.g. structures with different geometries than that shown in FIG. 4, comprising structural elements similar to those shown in FIG. 4, all of which structures and methods being, therefore, within the scope of the present disclosure.

The method 400 may begin with processing the surface of a silicon layer, such as e.g. the silicon layer 402, to achieve a certain target silicon surface smoothness and remove surface oxide (box 502).

When silicon being used in the silicon layer 402 is a crystalline silicon, then differentiation could be made with respect to selecting a particular orientation of the crystalline structure of silicon being at the surface of the layer 402. As is well-known, silicon may have a regular crystal structure, with silicon having a diamond cubic structure with a lattice spacing of about 0.543 nm. When cut into wafers, the surface of such silicon may be aligned in one of several relative directions referred to as “crystal orientations” defined by the Miller index, with (100) or (111) faces being the most common for silicon (but (110) face is also possible). Orientation is important since many of a single crystal's structural and electronic properties are highly anisotropic, with the Si(100) orientation for wafers currently being the industry standard for conventional IC fabrication. Considerations with respect to providing the interface layer 408 as described herein are applicable for all Si orientations, i.e. Si(100), Si(111), and Si(110) orientations, however the specific processing steps may vary and may yield more favorable or less favorable results depending on the particular orientation selected when providing the silicon layer 402.

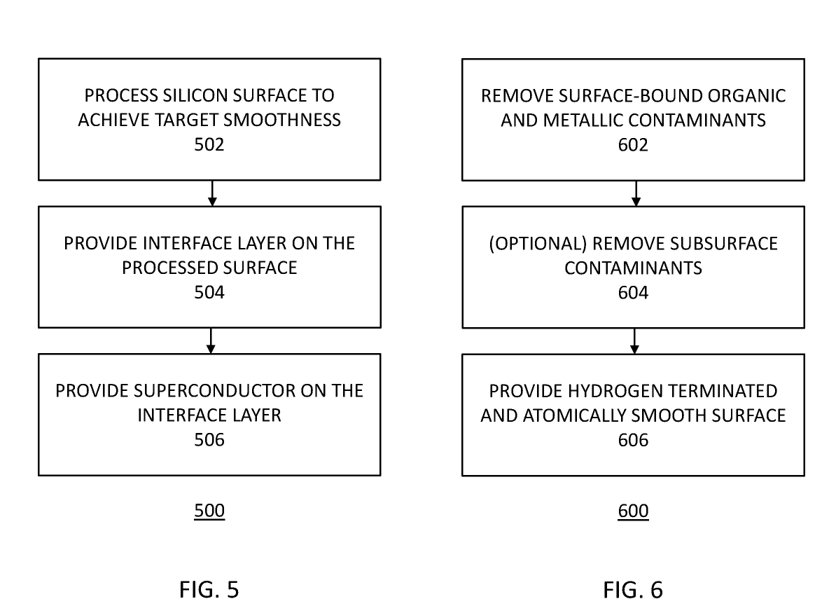

In some embodiments, processing the surface of the silicon layer 402 to achieve a target smoothness, e.g. to achieve an atomically flat surface, may be performed as shown in FIG. 6 with a method 600.

First, the silicon layer 402 may be cleaned to remove surface-bound organic and metallic contaminants (box 602). In some embodiments, cleaning may be carried out using e.g. a series of peroxide containing solutions known as Standard Clean 1 (SC1) and Standard Clean 2 (SC2), which are part of a standard cleaning procedure known as an RCA clean. In a first step of such a cleaning procedure, the silicon wafer may be immersed in a peroxide containing solution of diluted ammonium hydroxide between 23 and 100 degrees Celsius, e.g. between 60 and 80 degrees Celsius, for about 1 to 10 minutes, including all values and ranges therein for both the temperature and the time ranges. This step may remove organic layer from the silicon surface and grow a thin layer of silicon oxide on the surface. In a second step, the silicon wafer may be immersed in a peroxide containing solution of diluted hydrochloric acid between 23 and 100 degrees Celsius, e.g. between 60 and 80 degrees Celsius, for about 1 to 10 minutes, including all values and ranges therein for both the temperature and the time ranges. This step may remove surface-bound metallic contamination from the surface of the silicon layer 402.

Next, optionally, the silicon layer 402 may be further processed to remove subsurface contamination (box 604). Such subsurface contamination may be present e.g. as a result of preceding chemical mechanical polishing (CMP) which may have been applied to the silicon layer 402. In some embodiments, subsurface contamination may be removed by using conventional thermal oxidation configured to grow a relatively thick layer of silicon oxide on top of the surface of the silicon layer 402. For example, the silicon oxide layer may be between 10 and 1000 nm, including all values and ranges therein. Such oxide growth may incorporate possible subsurface defects into the oxide layer. In turn, the oxide layer may subsequently be removed using an immersion of the substrate comprising the oxidized silicon layer 402 in aqueous hydrofluoric acid (HF), which may optionally be buffered with ammonium fluoride (NH₄F), for the time required to remove the thermal oxide layer. As a result of this processing, the surface of the silicon layer 402 may be made hydrogen terminated, but the surface roughness could still be above the target smoothness level (i.e. the surface may still be too rough).

The surface may then be made both hydrogen terminated and atomically smooth with micron-sized or larger long terraces that are several hundreds of nanometers in width (box 606). This may be done by immersing the silicon wafer that results either from the processing of the box 602 or box 604 into a solution containing only aqueous 40% ammonium fluoride. In some embodiments, the ammonium fluoride may be degassed of air by e.g. bubbling/sparging with nitrogen (N₂) or argon (Ar) gas. Such degassing may be advantageous because, if not done, the dissolved oxygen may locally oxidize the silicon surface and form an undesirable etch pit in an otherwise smooth terrace. Following the processing with the aqueous 40% ammonium fluoride solution, the surface of the silicon layer 402 may be rinsed with or immersed in water, preferably water free of oxygen molecules.

One goal of hydrogen termination described above is to remove surface oxide from the surface of the silicon layer. In other embodiments, other techniques for removing surface oxide from the silicon layer may be employed, all of which are within the scope of the present disclosure.

As a result of processing as e.g. described above, the surface of the silicon layer 402 can be made atomically flat, e.g. having a surface roughness below a certain threshold, e.g. 1-2 nm root mean square (RMS). In general, as used herein, “atomically flat” may be used to describe a surface that is atomically smooth on a terrace of given dimensions. For example, for Si(111) surfaces, the dimension of a terrace width is generally dominated by the wafer miscut away from the (111) plane, which could be several hundreds of nanometers if the miscut is less than 1 degree. At the end of a terrace, the next terrace may be one monolayer, or one or a few silicon atoms in height, lower and should have similar dimensions of flatness. Atomic flatness, which may be assessed e.g. by Atomic Force Microscopy (AFM) or Scanning Tunneling Microscopy (STM), is preferably in the range of unit cell dimensions of Si. Since for e.g. Si(111) the step height between layers is about 0.6 nm, and the roughness on a terrace could be less than 0.5 nm. Two steps could also be combined together, yielding the roughness of about 0.6*2 nm which could still be acceptable and considered to be “atomically” flat in some implementations. Similar calculations may be provided for other Si faces and are within the scope of the present disclosure.

Processing of the surface of the silicon layer 402 in box 502 as illustrated in the method 600 shown in FIG. 6 may be particular advantageous for Si(111) surfaces in that applying the method 600 to Si(111) would yield surfaces that are more smooth than those that would be obtained starting with Si(100) or Si(110) surfaces. However, processing of the method 600 may be applied to Si(100) or Si(110) surfaces as well. Furthermore, in other embodiments, other techniques for providing relatively smooth surfaces with hydrogen termination, as may be known in the art, may be used as well.

Following the processing of box 502, the silicon layer 402 with the hydrogen-terminated surface may be moved quickly, e.g. within 5-60 minutes, to the next processing stage because the hydrogen termination is not stable in air and may slowly oxidize to form spurious TLS's which are detrimental to quantum circuit operation. With respect to this issue Si (111) silicon layers may, again, be particularly advantageous because hydrogen terminated Si(111)-surfaces may be more stable than hydrogen terminated Si(100)-surfaces.

The method 500 may then proceed with applying one or more of surface modification techniques to create an interface layer, e.g. the interface layer 408, on the atomically flat and hydrogen terminated surface of the silicon layer 402 (box 504). Materials used for the interface layer 408 may be divided into a number of classes, with different surface modification techniques being appropriate for different classes of materials.

As briefly described above, one class of materials which could be used to form the interface layer 408 include organic-based materials. An interface layer formed in box 504 of organic-based materials could be provided in a form of a relatively thin organic layer directly covalently bound to the silicon atoms of the surface of the silicon layer 402. Such an organic layer would enable chemical passivation and stability of the otherwise unstable hydrogen terminated surface that was the result of the processing of box 502. In some embodiments, such an organic interface layer 408 may be provided by bonding of methyl (—CH3) groups or alkynyl (—C≡CH, or —C≡C—CH3) bonds, which could bond with nearly all atop silicon atoms on the surface of the silicon layer 402. In other embodiments, such an organic interface layer 408 may be provided by ethyl termination (—CH2CH3) of the hydrogen terminated surface of the silicon layer 402 or by other alkyl termination (-octyl or -allyl) with larger groups. While the latter examples may not be able to fully terminate all silicon atoms on the surface of the silicon layer 402, they may still be able to sufficiently minimize the formation of electrically defect trap states, and, hence, may still lead to reduced losses due to reduced amounts of spurious TLS's. For example, even though the octyl and ethyl terminated surfaces are known not to cover every Si atom, the resulting sites in between have been shown to be Si—H sites that are more protected from oxidation and low trap state densities are observed even after long exposure to air.

In some embodiments, forming such organic interface layers 408 may include, first, converting the hydrogen terminated surface of the silicon layer 402 to a chlorine-terminated (i.e. Si—Cl terminated) surface using e.g. a wet-chemical chlorination step which may e.g. involve PCIS with a radical initiator, followed by reaction with appropriate alkyl-Grignard or organo-zinc complexes, and final solvent rinses. Since such an interface layer would be amourphous and, therefore, likely to be lossy in terms of spurious TLS's, preferably such a layer would be relatively thin, with the thickness of the resulting organic interface layer 408 being on the order of a few angstroms to a few nanometers. In this context, surface-bound organic materials with fewer rotation and vibration degrees of freedom, such as e.g. methyl, ethynyl and propynyl, may be particularly advantageous for forming the interface layer 408.

As also briefly described above, another class of materials that could be used to form the interface layer 408 include metal-based materials. Such a metallic surface interface layer 408 could be formed on top of the silicon layer 402 by deposition of metal under relatively gentle conditions, so that the interface between the metal of the interface layer 408 and the silicon of the silicon layer 402 is still relatively smooth, e.g. with surface roughness not exceeding a few nanometers, and preferably does not lead to formation of lossy or defective states (e.g. no dangling bonds). In some embodiments, materials for such an interface layer could be those that become superconducting under the qubit operational temperatures and that do not form silicides, alloys, or eutectics with typical subsequent (backend) post-processing at temperatures of 400-450 degrees Celcius. Some examples include evaporation or sputtering of aluminum (Al), indium (In) or niobium (Nb), atomic layer deposition (ALD) of titanium nitride (TiN), sputtering of niobium titanium alloy (NbTi), and electroplating of Indium (In) or niobium (Nb). In the embodiments where In is electroplated, it may be possible to also smoothen the surface with a post electroplate annealing step.

In some embodiments, deposition of a metal-based interface layer 408 may be carried out to avoid nitride based materials that are formed by reactive sputtering using nitrogen plasma since this may generate a thin layer of nitride at the surface of the silicon layer 402 prior to the deposition of the metallic interface layer 408.

The thickness of such metal-based interfacial layers may be selected to be thick enough to prevent any subsequent formation of silicon nitride below the interface layer 408 e.g. during reactive sputtering with nitrogen to form the upper superconductor 404. Another consideration for selecting the thickness of a metal-based interface layer 408 is that the layer would preferably be sufficiently thin so that the bulk of the superconductivity comes from the upper superconductor 404 rather than from the interface layer 408. In some embodiments, metal-based interface layer 408 may be on the order of 1-30 nm, including all values and ranges therein.

In still further embodiments, the interface layer 408 may include a combination, e.g. a stack, of two or more layers of the two classes of materials described above. In some such embodiments, the interface layer 408 may be provided by, first, providing an organic-based layer on the surface of the silicon layer 402, using any of the techniques described above for the organic-based layers, followed by a deposition of a metal-based layer, using any of the techniques described above for the metal-based layers. The interface layer 408 formed by such a combination of materials may be desirable because it could enable a more gentle deposition of metal relative to only employing metal-based interface layers described above. One example is the electroplating on niobium, which can be done with non-protic solvents, but requires the formation of NbFₓ compounds, where “x” indicates that niobium (Nb) and fluorine (F) could be provided in various ratios, e.g. as NbF₅ or other ionic species. Residual F could lead to surface etching of hydrogen terminated silicon surface (which results from the processing of box 502) under the electroplating conditions, but alkyl-terminated silicon surfaces are known to be significantly more stable to fluorine species and may enable the deposition of Nb using electrochemical means.

In some embodiments of the interface layer 408 provided by sequential deposition of organic-based and metal-based layers, the organic layer may ultimately go away during deposition of the metal layer but may act to minimize inter-diffusion of the metal with the underling silicon layer 402 during the initial stages of the energy applied to the surface of the silicon layer 402 during sputtering or evaporation. In other embodiments, at least parts of the organic layer may remain following deposition of the metal-based material of the interface layer 408 and may e.g. act as a means to keep the surface of the silicon layer 402 more isolated from the superconductor(s) deposited over it and/or act to reduce interface roughness.

Once the interface layer 408 is formed, the method 400 may proceed with depositing the superconductor 404 on or over the interface layer 408 using any of the known techniques for depositing such materials. For example, physical vapor deposition (PVD), chemical vapor deposition (CVD), or ALD may be used to deposit the superconductor 404.

For example, in physical vapor deposition, a workpiece (i.e. the substrate with the interface layer 408 provided on or over the silicon layer 402, possibly patterned to form a desired pattern of the superconductor 404) may be placed in a process chamber. A reactive gas, such nitrogen, is supplied to the process chamber. An inert gas, such as argon, may optionally be supplied into the process chamber as well. A metal target may be positioned in the process chamber and formed of a suitable superconductive metal. The metal target may be biased by a DC source. The workpiece, or worktable, may also be biased, by an AC source. During deposition, a plasma, e.g. nitrogen plasma, forms and is localized around the target due to magnets positioned proximal to or behind the target. The plasma bombards the target sputtering away the metal atoms as a vapor, which is then deposited on the workpiece. The process may continue for a time period in the range of e.g. 1 second to 20 minutes or more to deposit the superconductor 404 of the desired thickness. In such a scenario, having an interface layer 408 that is more plasma-stable than a surface of the silicon layer 402 would typically be, is advantageous because it may prevent or decrease formation of silicon nitride between the silicon layer 402 and the deposited superconductor 404.

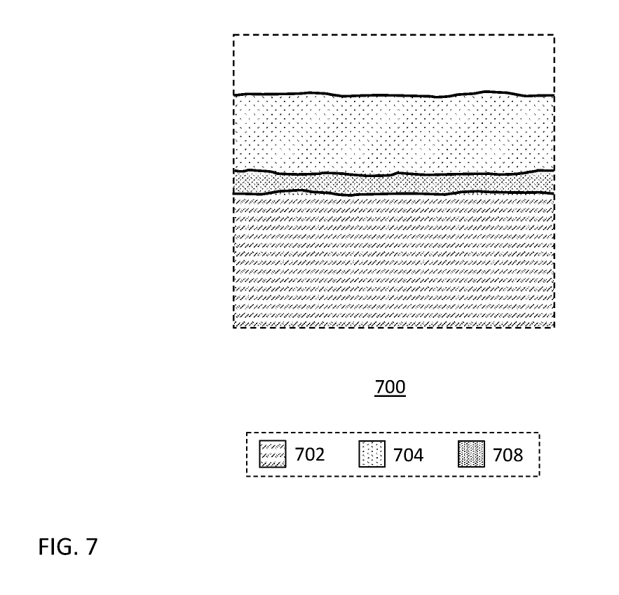

FIG. 7 provides a schematic illustration of a real-life structure 700 comprising an interface layer 708 configured to prevent/minimize formation of a silicon nitride layer at a superconductor-silicon interface, according to some embodiments of the present disclosure. As can be seen, FIG. 7 is drawn to reflect example real world process limitations, in that the features are not drawn with precise right angles and straight lines. As shown, FIG. 7 represents a cross-section view similar to that shown in FIG. 4. FIG. 7 illustrates a structure comprising an interface layer 708 provided over a silicon layer 702, e.g. a silicon substrate, and capped with a superconductor layer 704, as could be visible in e.g. a scanning electron microscopy (SEM) image or a transmission electron miscroscope (TEM) image. In such an image of a real structure, possible processing defects could also be visible, such as e.g. particles in the film, discontinuities in one or more of the layers, in particular discontinuities of the interface layer 708, egregious surface roughness that would degrade superconductivity, voids, and intermixing between layers (i.e. non-discrete interfaces).

A legend provided within a dashed box at the bottom of FIG. 7, as well as a legend provided at the bottom of FIG. 4, is used to indicate different elements shown in FIGS. 4 and 7, so that these figures are not cluttered by many reference numerals. Moreover, similar reference numerals in FIGS. 4 and 7 are used to illustrate similar elements in the figures. When provided with reference to one of the figures, discussions of these elements are applicable to the other figure, unless stated otherwise. Thus, in the interests of brevity, discussions of similar elements are not repeated for each of the figures.

Some Examples in accordance with various embodiments of the present disclosure are now described.

Example 1 provides a quantum circuit component including a silicon layer positioned over, on, or forming a part of, a substrate; an interface layer disposed on a surface of the silicon layer; and a superconductive material (a bulk superconductor) positioned on the interface layer, where an amount of nitrogen in the interface layer is below a predefined threshold.

Example 2 provides the quantum circuit component according to Example 1, where the interface layer includes methyl, alkynyl, ethyl, or alkyl groups.

Example 3 provides the quantum circuit component according to Example 2, where a thickness of the interface layer is between 0.1 and 10 nanometers.

Example 4 provides the quantum circuit component according to Example 1, where the interface layer includes one or more of aluminum (Al), indium (In), titanium (Ti), titanium nitride (TiN), niobium (Nb), and an alloy of niobium and titanium (NbTi).

Example 5 provides the quantum circuit component according to Example 4, where a thickness of the interface layer is between 1 and 30 nanometers.

Example 6 provides the quantum circuit component according to Example 1, where the interface layer includes an organic layer disposed over or on the surface and a metallic layer disposed over or on the organic layer.

Example 7 provides the quantum circuit component according to Example 6, where the organic layer includes methyl, alkynyl, ethyl, or alkyl groups and/or the metallic layer includes one or more of aluminum (Al), indium (In), titanium (Ti), titanium nitride (TiN), niobium (Nb), and an alloy of niobium and titanium (NbTi).

Example 8 provides the quantum circuit component according to Example 7, where a thickness of the organic layer is between 0.1 and 10 nanometers and/or a thickness of the metallic layer is between 1 and 30 nanometers.

Example 9 provides the quantum circuit component according to any one of the preceding Examples, where the superconductive material forms a coupling resonator of a transmon qubit.

Example 10 provides the quantum circuit component according to any one of the preceding Examples, where the superconductive material is a bulk superconductor.

Example 11 provides a method of fabricating a quantum circuit device, the method including processing a surface of a silicon layer to obtain the surface having a surface roughness below a predefined threshold, e.g. 1-2 root mean squared (RMS) nm; following said processing of the surface of the silicon layer, providing an interface layer in the surface, the interface layer configured to prevent or decrease formation of nitrogen-containing compounds between the surface and a superconductive material; and depositing a layer of the superconductive material (a bulk superconductor) on the interface layer.

Example 12 provides the method according to Example 11, where said processing of the surface of the silicon layer includes removing from the surface surface-bound organic and metallic contaminants, and following said removing of the organic and metallic contaminants, removing a surface oxide from the silicon layer.

Example 13 provides the method according to Example 12, where removing the surface oxide includes providing a hydrogen termination on the surface.

Example 14 provides the method according to Example 13, where said processing of the surface of the silicon layer further includes, following said removing of the organic and metallic contaminants and prior to said providing the hydrogen termination on the surface, processing the silicon layer to remove subsurface contamination.

Example 15 provides the method according to any one of Examples 11-14, where the interface layer includes an organic layer.

Example 16 provides the method according to Example 15, where providing the interface layer includes covalently bonding methyl, alkynyl, ethyl, or/and alkyl groups to at least some of a plurality of silicon (Si) atoms on the surface of the silicon layer.

Example 17 provides the method according to Examples 15 or 16, where a thickness of the interface layer is between 0.1 and 10 nanometers.

Example 18 provides the method according to any one of Examples 11-14, where the interface layer includes a metallic layer.

Example 19 provides the method according to Example 18, where providing the interface layer includes providing a layer of metal by one or more of evaporation, chemical vapor deposition (CVD), atomic layer deposition (ALD), electroless deposition and electroplating.

Example 20 provides the method according to Examples 18 or 19, where the interface layer includes one or more of aluminum (Al), indium (In), titanium (Ti), titanium nitride (TiN), niobium (Nb), and an alloy of niobium and titanium (NbTi).

Example 21 provides the method according to any one of Examples 18-20, where a thickness of the interface layer is between 1 and 30 nanometers.

Example 22 provides the method according to any one of Examples 11-14, where the interface layer includes an organic layer disposed over or on the surface of the silicon layer and a metallic layer disposed over or on the organic layer.

Example 23 provides the method according to Example 22, where providing the organic layer of the interface layer includes covalently bonding methyl, alkynyl, ethyl, or alkyl groups to at least some of a plurality of silicon (Si) atoms on the surface of the silicon layer.

Example 24 provides the method according to Examples 22 or 23, where a thickness of the organic layer is between 0.1 and 5 nanometers.

Example 25 provides the method according to any one of Examples 22-24, where providing the metallic layer of the interface layer includes providing a layer of metal by one or more of evaporation, chemical vapor deposition (CVD), atomic layer deposition (ALD), electroless deposition, and electroplating.

Example 26 provides the method according to any one of Examples 22-25, where the metallic layer includes one or more of aluminum (Al), indium (In), titanium nitride (TiN), niobium (Nb), and an alloy of niobium and titanium (NbTi).

Example 27 provides the method according to any one of Examples 22-26, where a thickness of the metallic layer is between 1 and 30 nanometers.

Example 28 provides the method according to any one of Examples 11-27, where the surface is a Si(111) surface.

Example 29 provides the method according to any one of Examples 11-27, where the surface is a Si(100) surface.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

1. A quantum circuit component comprising:
a silicon layer disposed over, on, or forming a part of, a substrate;
an interface layer disposed on a surface of the silicon layer; and
a superconductive material disposed on the interface layer,
wherein an amount of nitrogen in the interface layer is below a predefined threshold.

2. The quantum circuit component according to claim 1, wherein the interface layer comprises methyl, alkynyl, ethyl, or alkyl groups.

3. The quantum circuit component according to claim 2, wherein a thickness of the interface layer is between 0.1 and 10 nanometers.

4. The quantum circuit component according to claim 1, wherein the interface layer comprises one or more of aluminum (Al), indium (In), titanium (Ti), titanium nitride (TiN), niobium (Nb), and an alloy of niobium and titanium (NbTi).

5. The quantum circuit component according to claim 4, wherein a thickness of the interface layer is between 1 and 30 nanometers.

6. The quantum circuit component according to claim 1, wherein the interface layer comprises an organic layer disposed over or on the surface and a metallic layer disposed over or on the organic layer.

7. The quantum circuit component according to claim 6, wherein the organic layer comprises methyl, alkynyl, ethyl, or alkyl groups and/or the metallic layer comprises one or more of aluminum (Al), indium (In), titanium (Ti), titanium nitride (TiN), niobium (Nb), and an alloy of niobium and titanium (NbTi).

8. The quantum circuit component according to claim 7, wherein a thickness of the organic layer is between 0.1 and 10 nanometers and/or a thickness of the metallic layer is between 1 and 30 nanometers.

9. The quantum circuit component according to claim 1, wherein the superconductive material forms a coupling resonator of a transmon qubit.

10. The quantum circuit component according to claim 1, wherein the superconductive material is a bulk superconductor.

11. A method of fabricating a quantum circuit device, the method comprising:
processing a surface of a silicon layer to obtain the surface having a surface roughness below a predefined threshold;
following said processing, providing an interface layer in the surface, the interface layer configured to prevent or decrease formation of nitrogen-containing compounds between the surface and a superconductive material;
depositing a layer of the superconductive material on the interface layer.

12. The method according to claim 11, wherein said processing comprises:
removing from the surface organic and metallic contaminants, and following said removing of the organic and metallic contaminants, removing a surface oxide from the silicon layer.

13. The method according to claim 12, wherein removing the surface oxide comprises providing a hydrogen termination on the surface.

14. The method according to claim 13, wherein said processing further comprises:
following said removing of the organic and metallic contaminants and prior to said providing the hydrogen termination on the surface, processing the silicon layer to remove subsurface contamination.

15. The method according to claim 11, wherein the interface layer comprises an organic layer.

16. The method according to claim 15, wherein providing the interface layer comprises:
covalently bonding methyl, alkynyl, ethyl, or/and alkyl groups to at least some of a plurality of silicon (Si) atoms on the surface of the silicon layer.

17. The method according to claim 15, wherein a thickness of the interface layer is between 0.1 and 10 nanometers.

18. The method according to claim 11, wherein the interface layer comprises a metallic layer.

19. The method according to claim 18, wherein providing the interface layer comprises providing a layer of metal by one or more of evaporation, chemical vapor deposition (CVD), atomic layer deposition (ALD), electroless deposition and electroplating.

20. The method according to claim 18, wherein the interface layer comprises one or more of aluminum (Al), indium (In), titanium (Ti), titanium nitride (TiN), niobium (Nb), and an alloy of niobium and titanium (NbTi).

21. The method according to claim 18, wherein a thickness of the interface layer is between 1 and 30 nanometers.

22. The method according to claim 11, wherein the interface layer comprises an organic layer disposed over the surface of the silicon layer and a metallic layer disposed over the organic layer.

23. The method according to claim 22, wherein providing the organic layer of the interface layer comprises:
covalently bonding methyl, alkynyl, ethyl, or alkyl groups to at least some of a plurality of silicon (Si) atoms on the surface of the silicon layer.

24. The method according to claim 22, wherein the metallic layer comprises one or more of aluminum (Al), indium (In), titanium nitride (TiN), niobium (Nb), and an alloy of niobium and titanium (NbTi).

25. The method according to claim 11, wherein the surface is a Si(111) surface.
